(19) United States
(12) Patent Application Publication
(10) Pub. No.: US 2007/0249118 A1
(43) Pub. Date: Oct. 25, 2007

(54) SEMICONDUCTOR DEVICE AND METHOD OF MANUFACTURING THE SAME

(75) Inventors: Kiyonori Oyu, Tokyo (JP); Jun Sasaki, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/736,991

(22) Filed: Apr. 18, 2007

(30) Foreign Application Priority Data
Apr. 20, 2006 (JP) 2006-116541

(51) Int. Cl. H01L 21/8242; H01L 29/94; H01L 21/44

(52) U.S. Cl. 438/241; 438/597; 257/296

(57) ABSTRACT

Recessed portions (passages) are formed in a surface of a passivation film so as to eliminate an adverse influence from air bubbles that would be generated between a surface of a semiconductor wafer and a surface protection sheet covering the surface of the semiconductor wafer during plasma etching a rear face of the semiconductor wafer after a back-grinding process.

This application claims priority to prior Japanese patent application JP2006-116541, the disclosure of which is incorporated herein by reference.

### BACKGROUND OF THE INVENTION

1. Field of the Invention

The present invention relates to a semiconductor device having at least a semiconductor element formed on a primary surface of a semiconductor wafer and a passivation film formed so as to cover the semiconductor element. The present invention also relates to a method of manufacturing such a semiconductor device.

2. Description of the Related Art

In a currently used semiconductor device, as shown in FIG. 1, semiconductor elements 3 are formed on a primary surface 2 of a semiconductor wafer 1. Then, in a final manufacturing process of a wafer state, a polyimide coating film 4 (passivation film) is formed for passivation. In a semiconductor device having memories such as DRAM, recovery fuses 5 are provided for replacing defective memories with normal memories.

When back-grinding is carried out in the wafer state after the formation of the polyimide coating film 4, a surface protection sheet 6 for back-grinding is attached to a surface of the polyimide coating film 4. Recently, plasma etching has been performed for a rear face of a back-ground wafer so as to remove grinding stress after the back-grinding process. The plasma etching process is performed in such a state that the surface protection sheet 6 has been attached to the wafer.

The plasma etching is performed in a vacuum processing apparatus. Accordingly, as shown in FIG. 2, air in opening portions (cavity portions) 7 for the fuses 5 expands to thereby generate air bubbles (or swelled spaces) 8 between the surface protection sheet 6 and a surface of the wafer to which the surface protection sheet 6 is attached. In this event, if there are no relief passages, the air bubbles 8 become large. Consequently, as shown in FIG. 3, the wafer 10 is in a floating state separated from an etching stage 11 in a vacuum chamber 9 for plasma etching.

As a result, plasma etching cannot be performed at a desired level. For example, if the wafer 10 is separated from the etching stage 11, the temperature of the semiconductor wafer 10 increases so as to deteriorate the surface protection sheet 6 attached to the surface of the semiconductor wafer 10. If the surface protection sheet 6 is deteriorated, it becomes unable to be peeled from the semiconductor wafer 10. The semiconductor wafer 10 becomes useless at that time.

Furthermore, if the semiconductor wafer 10 is separated from the etching stage 11, plasma 12 exerts an ununiform influence on the semiconductor wafer 10. Accordingly, optimum etching conditions cannot be achieved, thereby causing ununiform etching. Moreover, if air bubbles 8 are generated as described above, it is difficult to transfer the wafer 10 from the etching apparatus. The semiconductor wafer 10 may be dropped from a transfer system 13 or may be broken. Thus, the plasma etching has many disadvantages.

In recent years, semiconductor devices have used a stacked chip structure with chips having a thickness of 100 μm or less in order to increase an effective memory capacity per area or to incorporate a memory and a CPU into the same package. For reducing the thickness of chips, a back-grinding process is generally performed in a wafer state so as to thin the wafer. However, if the thickness of the chip is reduce to 100 μm in the wafer state, the wafer is warped due to grinding stress, thereby making it difficult to transfer the wafer.

Therefore, a polished finish process or a plasma etching process has been proposed in order to eliminate grinding stress (see “Thorough inspection of extra-thin chip assembly technology, devices, and elements,” in proceedings of symposium sponsored by Electronic Journal Inc., Kokuyo Hall, Japan, Oct. 26, 2005). In a polished finish process, metal contaminations caused by a back-grinding process remain on a finished surface in many cases. The metal contaminations reach a semiconductor device due to thermal hysteresis in a package assembly process. Consequently, device characteristics are degraded.

On the other hand, since a semiconductor substrate is etched under vacuum during a plasma etching process, metal contaminations caused by a back-grinding process are removed from the semiconductor substrate. As a consequence, metal is unlikely to remain on the etched surface. However, the aforementioned problems arise when a plasma etching process is performed to eliminate grinding stress after a back-grinding process.

### SUMMARY OF THE INVENTION

The present invention has been made in view of the above drawbacks. It is, therefore, an object of the present invention to eliminate an adverse influence from air bubbles that are generated between a surface of a semiconductor wafer and a back-grinding surface protection sheet covering the surface of the semiconductor wafer during a plasma etching process of a rear face of the semiconductor wafer after a back-grinding process and to perform a plasma etching process at a desired level.

In order to attain the above object, according to a first aspect of the present invention, there is provided a semiconductor device having a semiconductor wafer having a primary surface, a semiconductor element formed on the primary surface of the semiconductor wafer, and a passivation film provided so as to cover the semiconductor element. The passivation film has a recessed portion formed in a surface thereof.

The recessed portion may be configured to form a passage between the primary surface of the semiconductor wafer and a surface protection sheet used for a back-grinding process of the semiconductor wafer.

It is desirable that the passage is formed continuously on an overall surface of the semiconductor wafer.

It is also desirable that the passivation film includes a wall at a peripheral portion of the semiconductor wafer near an end of the passage extending from a central portion of the semiconductor wafer.

For example, the passivation film may comprise a polyimide coating film.

According to a second aspect of the present invention, there is provided a method of manufacturing a semiconductor device having a semiconductor wafer. This method includes forming a semiconductor element on a primary surface of a semiconductor wafer, forming a passivation film so as to cover the semiconductor element, forming an opening portion in the passivation film so as to extend through the passivation film, forming a recessed portion in a surface of the passivation film, forming a surface protection sheet on an upper surface of the passivation film, back-grinding the semiconductor wafer with use of the surface protection sheet, and plasma etching the semiconductor wafer in a state that the surface protection sheet is present on the upper surface of the passivation film.

The recessed portion may form a passage between the surface protection sheet and the primary surface of the semiconductor wafer.

It is desirable that the passage is formed continuously on an overall surface of the semiconductor wafer.

Air in the opening portion that generates a swelled space may be released through the passage from a peripheral portion of the semiconductor wafer during the plasma etching process.

The plasma etching process may be performed for removing grinding stress after the back-grinding process in a vacuum processing apparatus.

It is desirable that the recessed portion is formed by pressing a tool having irregularities against the surface of the passivation film after the forming process of the opening portion.

It is also desirable that a wall is formed at a peripheral portion of the semiconductor wafer near an end of the passage extending from a central portion of the semiconductor wafer.

The wall may be formed for preventing grinding water from being introduced from the peripheral portion of the semiconductor wafer into the passage during the back-grinding process

For example, the passivation film may comprise a polyimide coating film.

According to a third aspect of the present invention, there is provided a method of manufacturing a semiconductor device having a semiconductor wafer. This method includes forming a semiconductor element on a primary surface of a semiconductor wafer, forming a passivation film so as to cover the semiconductor element, forming an opening portion in the passivation film so as to extend through the passivation film, forming a surface protection sheet on an upper surface of the passivation film, forming a recessed portion in the surface protection sheet, back-grinding the semiconductor wafer with use of the surface protection sheet, and plasma etching the semiconductor wafer in a state that the surface protection sheet is present on the upper surface of the passivation film.

The recessed portion may form a passage between the surface protection sheet and the primary surface of the semiconductor wafer.

The plasma etching process may be performed for removing grinding stress after the back-grinding process in a vacuum processing apparatus.

For example, the passivation film may comprise a polyimide coating film.

Thus, according to the present invention, a recessed portion (irregularities) is formed in a surface of a passivation film (polyimide coating film) during formation of the passivation film as a final manufacturing process of a wafer state of a semiconductor device. With this structure, it is possible to eliminate an adverse influence from air bubbles that are generated between a surface of the semiconductor wafer and a back-grinding surface protection sheet covering the surface of the semiconductor wafer during a plasma etching process of a rear face of the semiconductor wafer after a back-grinding process and to perform a plasma etching process at a desired level.

According to the present invention, it is possible to suppress a temperature rise of the wafer to about 60° C. during the plasma etching. Therefore, deterioration of the surface protection sheet can be prevented. Furthermore, since the uniformity of etching is not impaired, the grinding stress can be removed uniformly. Further, it is possible to prevent transferring errors. As described above, according to the present invention, the conventional problems in a plasma etching process can be resolved. Therefore, it is possible to reduce process disadvantages to a large extent.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1 is a cross-sectional view showing a semiconductor device to which a surface protection sheet is attached after a final manufacturing process of a wafer state in the related art;

FIG. 2 is a cross-sectional view showing a wafer having a surface protection sheet attached thereto that has been introduced into a vacuum processing apparatus in the related art;

FIG. 3 is a schematic view showing a plasma etching apparatus for processing a semiconductor wafer in the related art;

FIG. 4 is a cross-sectional view showing a semiconductor wafer having a polyimide coating film formed thereon according to the present invention;

FIG. 5 is a cross-sectional view showing the semiconductor wafer to which a surface protection sheet is attached according to the present invention;

FIG. 6 is a plan view showing passages formed between the polyimide coating film and the surface protection sheet according to the present invention;

FIG. 7 is a schematic view showing a plasma etching apparatus for processing the semiconductor wafer according to the present invention;

FIG. 8 is a plan view showing the passages formed between the polyimide coating film and the surface protection sheet according to the present invention;

FIG. 9 is a cross-sectional view showing a semiconductor wafer having a polyimide coating film formed thereon according to the present invention; and

FIG. 10 is a cross-sectional view showing a peripheral portion of the semiconductor wafer to which a surface protection sheet is attached according to the present invention.

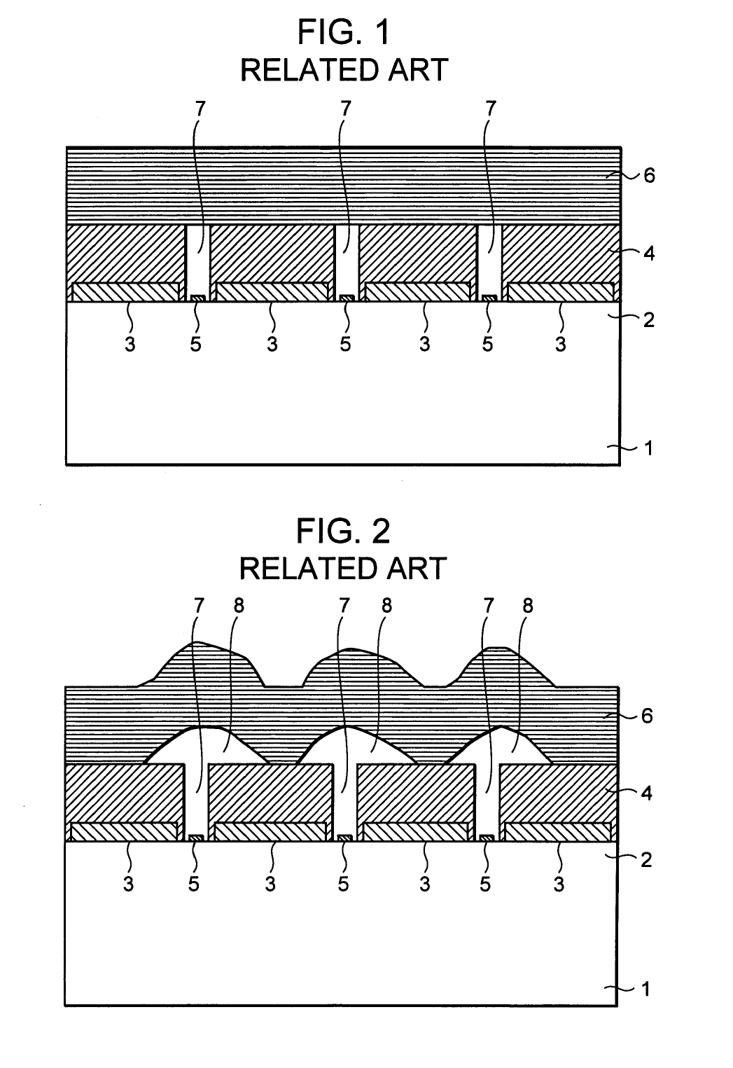

### DETAILED DESCRIPTION OF THE PREFERRED EMBODIMENTS

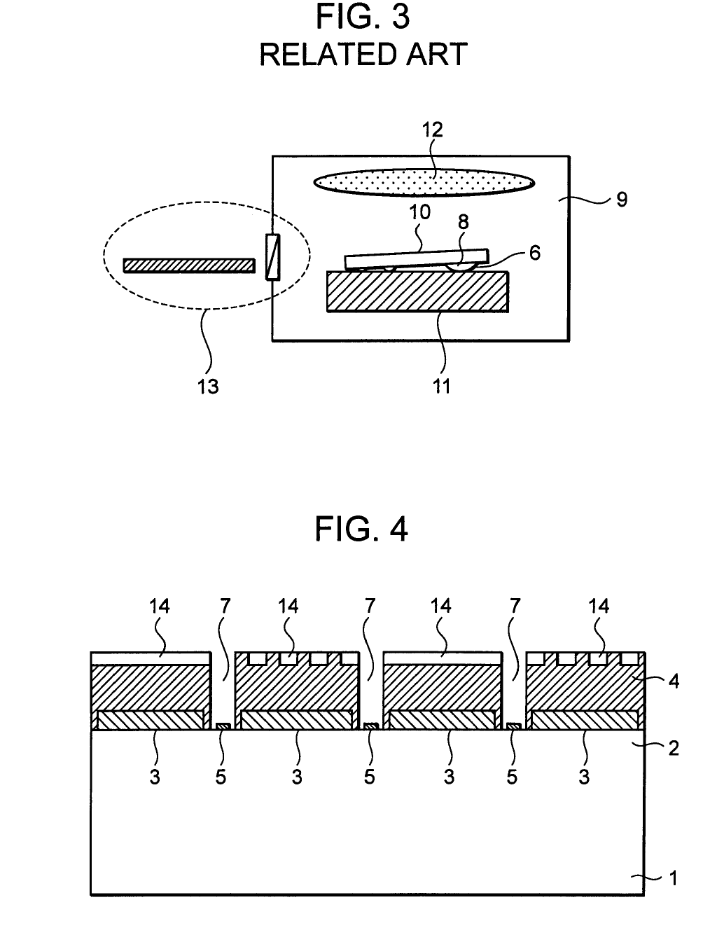

A semiconductor device according to embodiments of the present invention will be described below with reference to FIGS. 4 to 10.

As shown in FIG. 4, a semiconductor device according to the present invention includes a semiconductor wafer 1 and semiconductor elements 3 formed on a primary surface 2 of the semiconductor wafer 1. Wiring, electrodes, and an interlayer insulating film (not shown) are also formed on the primary surface 2 of the semiconductor wafer 1. The semiconductor device also includes a polyimide coating film (passivation film) 4 formed on the primary surface 2 of the semiconductor wafer 1 and recovery fuses (or electrode pad portions) 5 formed in opening portions 7 of the polyimide coating film 4. The polyimide coating film 4 has recessed portions 14 formed in a surface thereof.

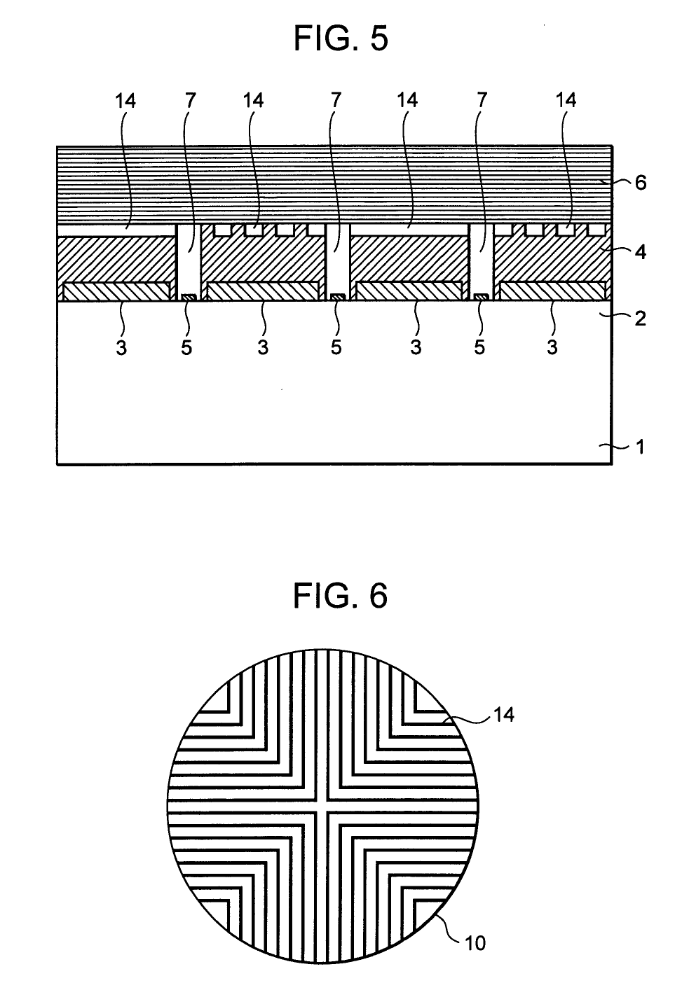

The recessed portions 14 are formed in the surface of the polyimide coating film 4 during a polyimide coating film formation process as a final manufacturing process of a wafer state of a semiconductor device. As shown in FIG. 5, the recessed portions 14 produce passages between the surface of the wafer 1 and a surface protection sheet 6, which is used for a back-grinding process in the wafer state before package assembly. Furthermore, as shown in FIG. 6, the recessed portions 14 are arranged such that the produced passages are formed continuously on the overall surface of the wafer.

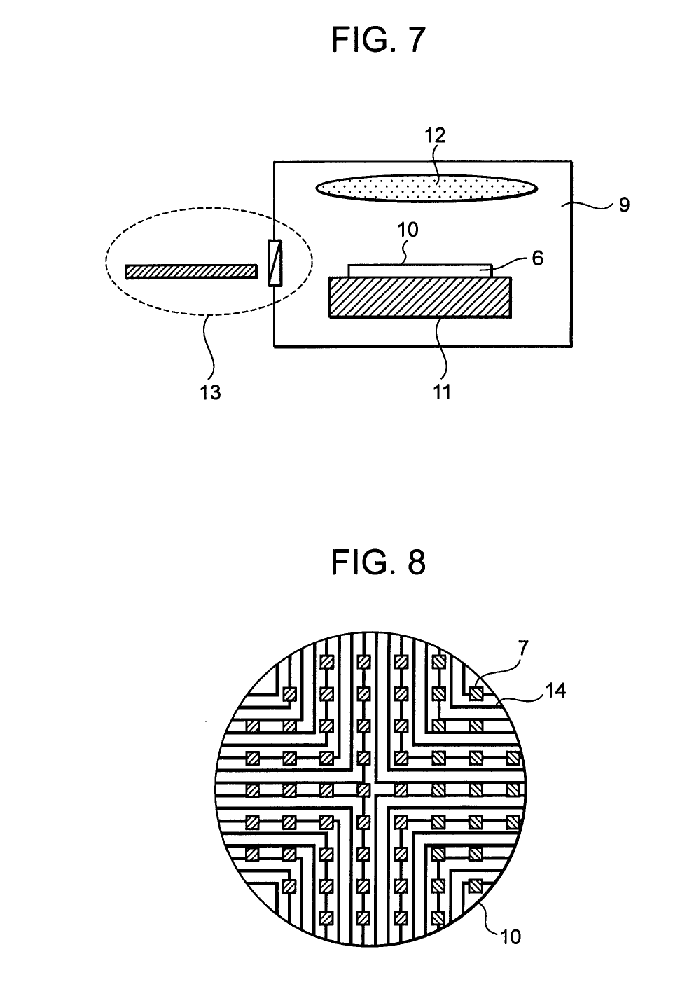

As a result, as shown in FIG. 7, even when the semiconductor wafer 10 with the surface protection sheet 6 attached to the semiconductor wafer 10 is introduced into a vacuum processing apparatus 9, no air bubbles are generated between the surface protection sheet 6 and the semiconductor wafer 10. Specifically, as shown in FIG. 8, air in the opening portions (cavity portions) 7, which generate air bubbles, is released from a periphery of the wafer 10 through the passages 14, which are continuously formed on the overall surface of the wafer. In this manner, the anomaly (or trouble) of the etching process or the anomaly (or trouble) of the transferring process can be prevented in the vacuum processing apparatus 9.

Subsequently, a method of manufacturing a semiconductor device according to the present invention will be described below.

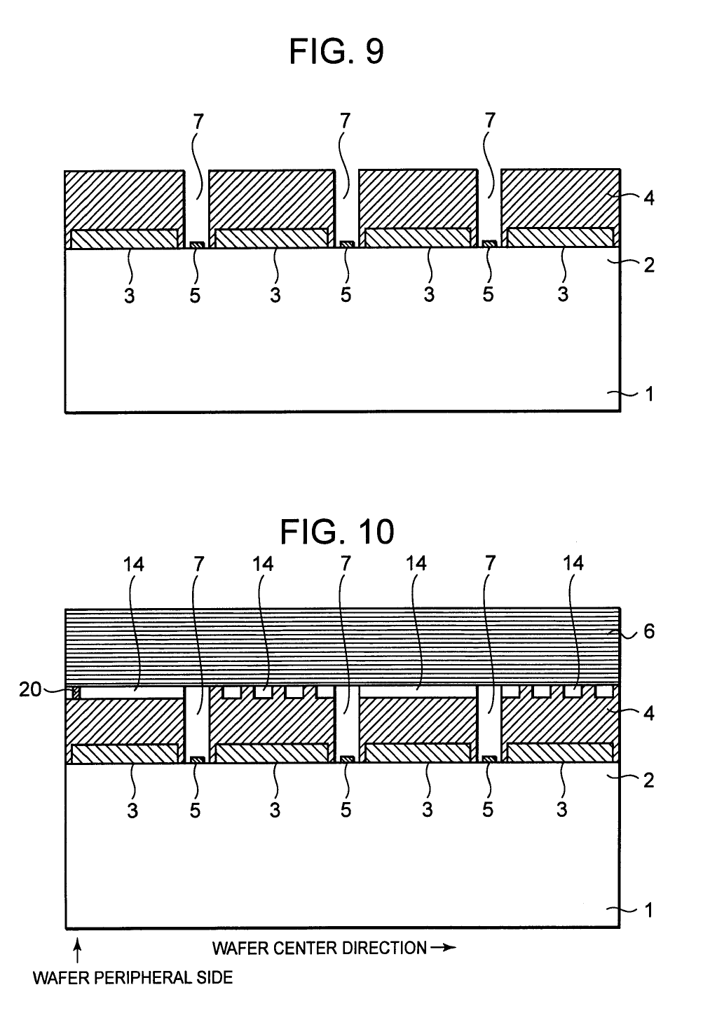

First, as shown in FIG. 9, semiconductor elements 3, wiring, electrodes, and an interlayer insulating film (not shown) are formed on a primary surface 2 of a semiconductor wafer 1. Then, a photosensitive polyimide coating film (passivation film) 4 is applied onto the semiconductor wafer 1 and developed so that opening portions 7 are formed in the polyimide coating film 4 for fuses (or electrode pad portions) 5. The polyimide coating film 4 has a thickness of about 5 μm.

Thereafter, a tool (not shown) is pressed against a surface of the polyimide coating film 4 so as to form recessed portions 14 having a depth of about 1 μm and a width of about 10 μm in the polyimide coating film 4 as shown in FIG. 4. Then, a baking process is performed at 350° C. so as to harden the polyimide coating film 4.

Next, treatment of the opening portions 7 in the polyimide coating film 4 and baking at 350° C. are carried out, respectively. Thus, the semiconductor wafer 1 having the semiconductor elements 3 formed thereon is completed. A back-grinding process is performed on the completed semiconductor wafer 1 so as to adjust the thickness of the semiconductor wafer 1 to a desired value. At that time, as shown in FIG. 5, a surface protection sheet 6 is attached to the semiconductor wafer 1 for protecting the surface of the semiconductor wafer 1 during the back-grinding process. In this example, the thickness of the semiconductor wafer 1 is reduced from 750 μm to 100 μm by a normal back-grinding process.

Thereafter, a plasma etching process is performed on the semiconductor wafer 1 with the surface protection sheet 6 in order to remove grinding stress after the back-grinding process. As shown in FIG. 7, the plasma etching process is performed within a vacuum processing apparatus 9 having a transfer system 13. The semiconductor wafer 10 is placed on an etching stage 11 in a state such that the back-ground surface of the semiconductor wafer 10 faces upward. In this event, the semiconductor wafer 10 is held on the etching stage 11 by a chuck, and the surface protection sheet 6 is brought into contact with the etching stage 11.

After the semiconductor wafer 10 has been transferred into the vacuum processing apparatus 9, the interior of the vacuum processing apparatus 9 is evacuated to 800 Pa. In a polyimide coating film having no irregularities on a surface thereof, air bubbles are generally generated as described in the related art. However, according to the present invention, no air bubbles are generated between the polyimide coating film 4 and the surface protection sheet 6.

The plasma etching process is performed under an atmosphere in which SF₆ gas and O₂ gas are mixed with each other. The degree of vacuum is set to be 300 Pa during etching. The temperature of the etching stage 11 is set to be 20° C. The temperature of the semiconductor wafer 10 on the etching stage 11 is increased to about 60° C. as the etching process proceeds. By this etching process, a rear face of the semiconductor wafer 10 is etched by about 5 μm. Since grinding stress is generally present within a depth of about 1 μm from the rear face of the semiconductor wafer 10, it can completely be removed by 5-μm etching. In a polyimide coating film having no irregularities on a surface thereof, air bubbles are generally generated as described in the related art. In this case, a semiconductor wafer 10 is separated from the etching stage 11, and the temperature of the wafer is increased to a temperature over 100° C. Furthermore, an etching process proceeds ununiformly on a surface of the wafer 10.

According to the present invention, the semiconductor wafer 10 is not lifted from the etching stage 11. Therefore, the temperature rise is about 60° C., and the etching process can have excellent uniformity. After the etching process, the interior of the vacuum processing apparatus 9 is released to an atmosphere. The processed wafer 10 is taken out of the vacuum processing apparatus 9 by the transfer system 13. Thus, the entire process is completed.

According to the present invention, no air bubbles are generated as described above. Therefore, no errors are caused in the transfer system 13. Subsequently, the semiconductor device is completed after a usual dicing process and a package assembly process.

The above embodiment has been described with the example of the passage pattern shown in FIGS. 6 and 8. However, any passage pattern may be used as long as all of portions containing air that generate air bubbles are connected to a periphery of a wafer by the passages.

Furthermore, as shown in FIG. 10, thin walls 20 may be provided at peripheral portions of the polyimide coating film 4 near ends of the passages 14 extending from a central portion of the wafer in order to prevent grinding water from being introduced from the periphery of the wafer into the passages 14 during the back-grinding process. The width of the thin walls 20 is set such that the thin walls 20 are broken by the evacuation.

In the above embodiment, the passages 14 are formed in the polyimide coating film 4. However, the passages 14 may be formed in the surface protection sheet 6.

As described above, the present invention is applicable to a semiconductor device used for assembly of a package having a plurality of stacked chips.

Although certain preferred embodiments of the present invention have been shown and described in detail, it should be understood that various changes and modifications may be made therein without departing from the scope of the appended claims.

What is claimed is:

1. A semiconductor device, comprising:
a semiconductor wafer having a primary surface;
a semiconductor element formed on the primary surface of the semiconductor wafer;
a passivation film provided so as to cover the semiconductor element; and
a recessed portion formed in a surface of the passivation film.

2. The semiconductor device according to claim 1, wherein:
the recessed portion is configured to form a passage between the primary surface of the semiconductor wafer and a surface protection sheet used for a back-grinding process of the semiconductor wafer.

3. The semiconductor device according to claim 1, wherein:
the recessed portion is formed continuously on an overall surface of the semiconductor wafer.

4. The semiconductor device according to claim 1, wherein:
a wall is formed on the passivation film at a peripheral portion of the semiconductor wafer near an end of the recessed portion extending from a central portion of the semiconductor wafer.

5. The semiconductor device according to claim 1, wherein:
the passivation film comprises a polyimide coating film.

6. A method of manufacturing a semiconductor device having a semiconductor wafer, comprising:
forming a semiconductor element on a primary surface of a semiconductor wafer;
forming a passivation film so as to cover the semiconductor element;
forming an opening portion in the passivation film so as to extend through the passivation film;
forming a recessed portion in a surface of the passivation film;
forming a surface protection sheet on an upper surface of the passivation film;
back-grinding the semiconductor wafer by using the surface protection sheet; and
plasma etching the semiconductor wafer in a state that the surface protection sheet is present on the upper surface of the passivation film.

7. The method according to claim 6, wherein:
the forming step of the surface protection sheet comprises forming a passage between the surface protection sheet and the primary surface of the semiconductor wafer with the recessed portion.

8. The method according to claim 6, wherein:
the forming step of the recessed portion comprises forming the recessed portion continuously on an overall surface of the semiconductor wafer.

9. The method according to claim 7, further comprising:
releasing air in the opening portion that generates an air bubble through the passage from a peripheral portion of the semiconductor wafer during the plasma etching.

10. The method according to claim 6, wherein:
the plasma etching is performed to remove grinding stress after the back-grinding in a vacuum processing apparatus.

11. The method according to claim 6, wherein:
the forming step of the recessed portion comprises pressing a tool having irregularities against the surface of the passivation film after forming the opening portion.

12. The method according to claim 6, further comprising:
forming a wall at a peripheral portion of the semiconductor wafer near an end of the recessed portion extending from a central portion of the semiconductor wafer.

13. The method according to claim 12, wherein:
the wall is formed to prevent grinding water from being introduced from the peripheral portion of the semiconductor wafer into the recessed portion during the back-grinding process

14. The method according to claim 6, wherein:
the passivation film comprises a polyimide coating film.

15. A method of manufacturing a semiconductor device having a semiconductor wafer, comprising:
forming a semiconductor element on a primary surface of a semiconductor wafer;
forming a passivation film so as to cover the semiconductor element;
forming an opening portion in the passivation film so as to extend through the passivation film;
forming a surface protection sheet on an upper surface of the passivation film;
forming a recessed portion in the surface protection sheet;
back-grinding the semiconductor wafer by using the surface protection sheet; and
plasma etching the semiconductor wafer in a state that the surface protection sheet is present on the upper surface of the passivation film.

16. The method according to claim 15, wherein:
the forming step of the surface protection sheet comprises forming a passage between the surface protection sheet and the primary surface of the semiconductor wafer with the recessed portion.

17. The method according to claim 15, wherein:
the plasma etching is performed to remove grinding stress after the back-grinding in a vacuum processing apparatus.

18. The method according claim 15, wherein:
the passivation film comprises a polyimide coating film.
